(19) United States
(12) Patent Application Publication
(10) Pub. No.: US 2026/0182145 A1
(43) Pub. Date: Jun. 25, 2026

(54) ORGANIC LIGHT EMITTING ELEMENT AND MANUFACTURING METHOD THEREOF

(71) Applicant: TAIZHOU GUANYU TECHNOLOGY CO., LTD., ZHEJIANG PROVINCE (CN)

(72) Inventors: YICHANG WANG, ZHEJIANG PROVINCE (CN); LI-CHEN WEI, TAICHUNG CITY (TW); KUO-CHENG HSU, TAICHUNG CITY (TW)

(21) Appl. No.: 19/383,719

(22) Filed: Nov. 9, 2025

(30) Foreign Application Priority Data
Dec. 19, 2024 (CN) 202411890813.2

(51) Int. Cl. H10K 50/856; H10K 50/818; H10K 71/60

(52) U.S. Cl. CPC H10K 50/856; H10K 50/818; H10K 71/60

(57) ABSTRACT

An organic light emitting element includes a substrate, a first electrode, a second electrode, a first organic light emitting layer, a first reflective surface, and a second reflective surface. The first electrode and the second electrode are disposed on the substrate. The first organic light emitting layer is disposed between the first electrode and the second electrode. The first reflective surface faces the first organic light emitting layer, wherein for light emitted from the first organic light emitting layer, the first reflective surface has a reflectance equal to or greater than 30%, and the second reflective surface has a reflectance greater than the reflectance of the first reflective surface.

### TECHNICAL FIELD

The disclosure relates to an organic light emitting element. More particularly, the disclosure relates to an organic light emitting element including an organic light emitting diode (OLED) structure.

### BACKGROUND

Currently, fine metal mask (FMM) is commonly used to coat light emitting layers of organic light emitting elements, or white light with color filters is used for the process. The pixel fineness or resolution produced by the above-mentioned processes is unsatisfactory.

### SUMMARY

In this disclosure, an organic light emitting element includes a substrate, a first electrode, a second electrode, a first organic light emitting layer, a first reflective surface, and a second reflective surface. The first electrode and the second electrode are disposed on the substrate. The first organic light emitting layer is disposed between the first electrode and the second electrode. The first reflective surface faces the first organic light emitting layer, wherein for light emitted from the first organic light emitting layer, the first reflective surface has a reflectance equal to or greater than 30%, and the second reflective surface has a reflectance greater than the reflectance of the first reflective surface.

In this disclosure, a method of manufacturing an organic light emitting element includes: providing a substrate; disposing a first electrode and a second electrode on the substrate; forming a first organic light emitting layer on the substrate, wherein the first organic light emitting layer is disposed between the first electrode and the second electrode; and forming a first reflective surface at a first surface of the first electrode or at a second surface of the first electrode opposite to the first surface, wherein for light emitted from the first organic light emitting layer, the first reflective surface has a reflectance equal to or greater than 30%.

In some embodiments, the first reflective surface faces away from a light emitting surface of the organic light emitting element, and the first reflective surface is closer to the light emitting surface than the second reflective surface.

In some embodiments, the first electrode is disposed between the second electrode and a light emitting surface of the organic light emitting element, the first electrode is a metal electrode, and a surface of the first electrode facing the second electrode includes the first reflective surface.

In some embodiments, the first electrode is disposed between the second electrode and a light emitting surface of the organic light emitting element, the first electrode is a transparent electrode, and the organic light emitting element further includes a reflective layer disposed between the substrate and the first electrode, wherein the reflective layer includes the first reflective surface.

In some embodiments, a first surface of the first electrode faces the second electrode, and a second surface of the first electrode opposite to the first surface faces the substrate and contacts the reflective layer.

In some embodiments, the organic light emitting element further includes: a third electrode disposed on the substrate, wherein the third electrode is a transparent electrode; and a second organic light emitting layer disposed between the third electrode and the second electrode, wherein the reflective layer is further disposed between the substrate and the third electrode.

In some embodiments, the first electrode is disposed between the second electrode and a light emitting surface of the organic light emitting element, the first electrode is a transparent electrode, and the organic light emitting element further includes a reflective layer disposed between the first electrode and the first organic light emitting layer, wherein the reflective layer includes the first reflective surface.

In some embodiments, the first electrode is disposed between the second electrode and a light emitting surface of the organic light emitting element, the first electrode is a transparent electrode, and the organic light emitting element further includes: a capping layer disposed on the first electrode; and a first reflective layer disposed between the capping layer and the first electrode, wherein the first reflective layer includes the first reflective surface.

In some embodiments, a first surface of the first electrode faces the capping layer and contacts the first reflective layer.

In some embodiments, the organic light emitting element further includes: a third electrode disposed on the substrate, wherein the third electrode is a transparent electrode; a second organic light emitting layer disposed between the third electrode and the second electrode; and a second reflective layer disposed between the capping layer and the second electrode, wherein the second reflective layer includes a third reflective surface.

In some embodiments, for light emitted from the second organic light emitting layer, the third reflective surface has a reflectance equal to or greater than 30%.

In some embodiments, the method of manufacturing an organic light emitting element further includes: manufacturing the first electrode using a metal material, such that the first surface of the first electrode facing the first organic light emitting layer includes the first reflective surface.

In some embodiments, the method of manufacturing an organic light emitting element further includes: manufacturing the first electrode using a transparent conductive material; and disposing a reflective layer on the first surface or the second surface of the first electrode, wherein the first electrode is disposed between a light emitting surface of the organic light emitting element and the second electrode.

In some embodiments, the method of manufacturing an organic light emitting element further includes: disposing a first reflective layer and a second reflective layer separated from each other on the substrate; and disposing a third electrode on the second reflective layer, wherein the first electrode is disposed on the first reflective layer, and the first electrode and the third electrode include a transparent conductive material.

In some embodiments, the method of manufacturing an organic light emitting element further includes: forming a second organic light emitting layer on the substrate; disposing a third electrode on the second organic light emitting layer, wherein the first electrode is disposed on the first organic light emitting layer; disposing a first reflective layer on the first electrode; and disposing a second reflective layer on the third electrode.

### BRIEF DESCRIPTION OF THE DRAWINGS

FIG. 1 is a top view exemplarily showing an intermediate product of an organic light emitting element.

FIG. 2A is a cross sectional view exemplarily showing an organic light emitting element.

FIG. 2B is a cross sectional view exemplarily showing an organic light emitting element.

FIG. 2C is a cross sectional view exemplarily showing an organic light emitting element.

FIG. 2D is a cross sectional view exemplarily showing an organic light emitting element.

FIG. 2E is a cross sectional view exemplarily showing an organic light emitting element. FIG. 2F is a cross sectional view exemplarily showing an organic light emitting element.

FIGS. 3A-3F show a method of manufacturing an organic light emitting element according to some embodiments.

FIG. 4 is a top view exemplarily showing an intermediate product of an organic light emitting element.

FIG. 5A is a cross sectional view exemplarily showing an organic light emitting element.

FIG. 5B is a cross sectional view exemplarily showing an organic light emitting element.

FIG. 5C is a cross sectional view exemplarily showing an organic light emitting element.

FIGS. 6A-6E show a method of manufacturing an organic light emitting element according to some embodiments.

FIG. 7A shows simulation results of spatial luminance distribution of an organic light emitting element according to some embodiments.

FIG. 7B shows simulation results of spatial luminance distribution of an organic light emitting element according to some comparative embodiments.

FIG. 7C shows simulation results of emission peak spectra of an organic light emitting element according to some embodiments.

FIG. 7D shows simulation results of emission peak spectra of an organic light emitting element according to some comparative embodiments.

### DETAILED DESCRIPTION

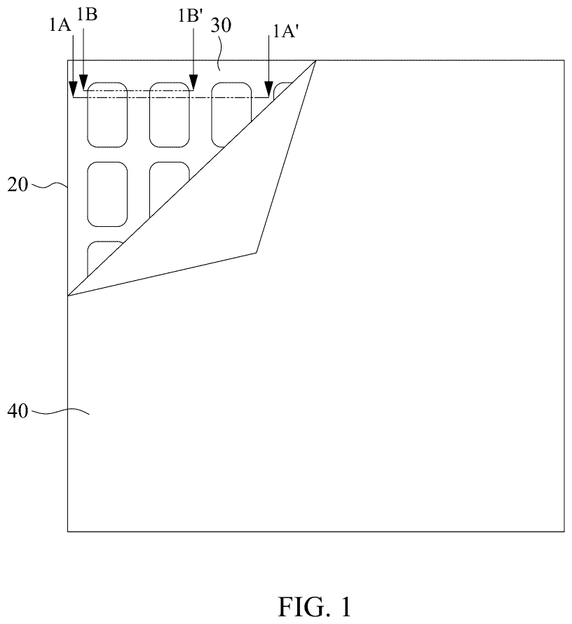

FIG. 1 is a top view exemplarily showing an intermediate product of an organic light emitting element 10. The organic light emitting element 10 has a light emitting layer 20 and a covering layer 40 disposed on the light emitting layer 20. For the light emitting layer 20, a spacer structure 30 may be designed to provide a recess array for accommodating a light emitting pixel array. In some embodiments, the spacer structure 30 may include a protrusion 310. In some embodiments, the spacer structure 30 may include a light sensitive material.

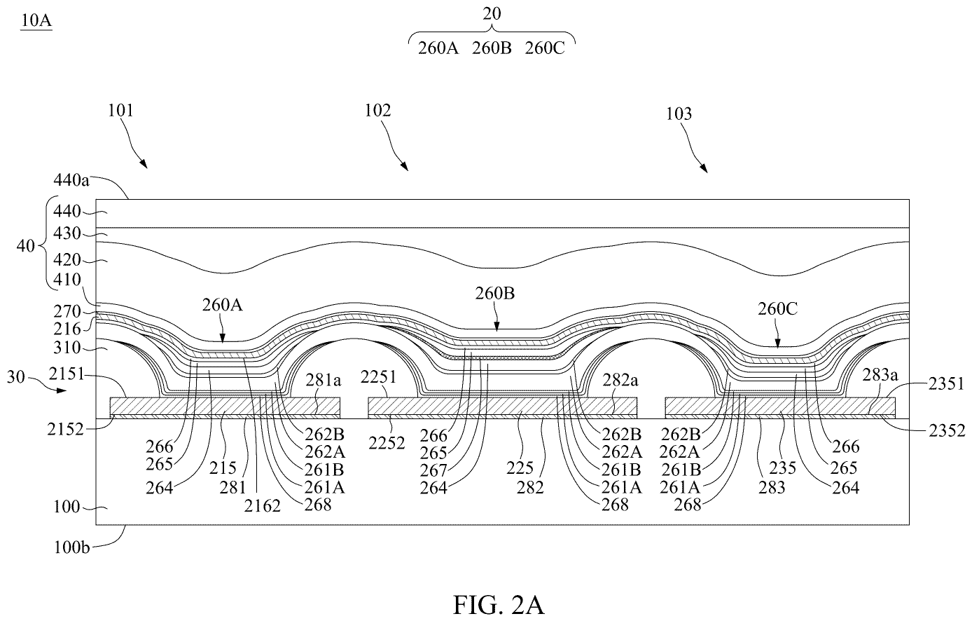

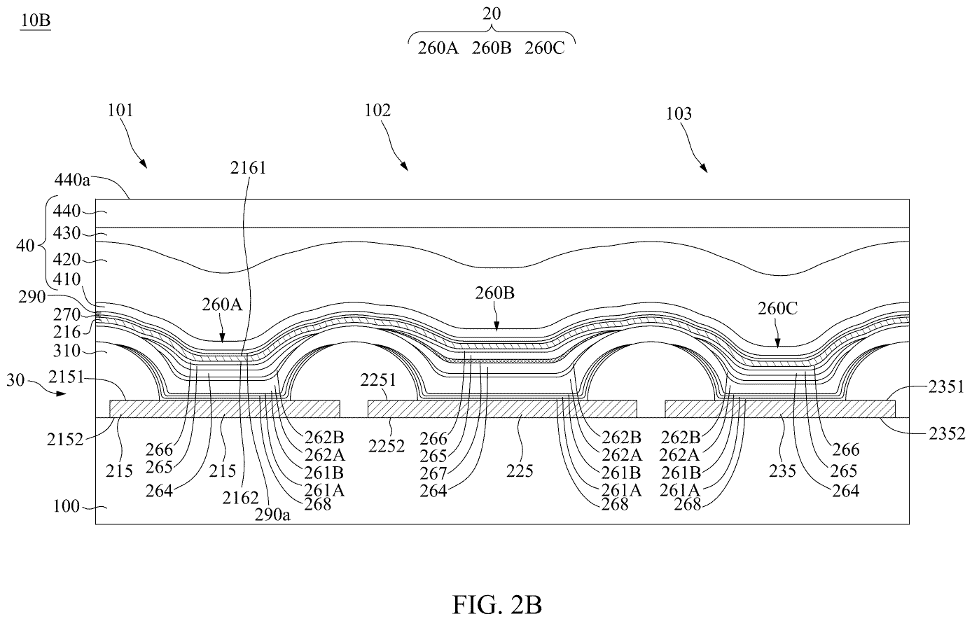

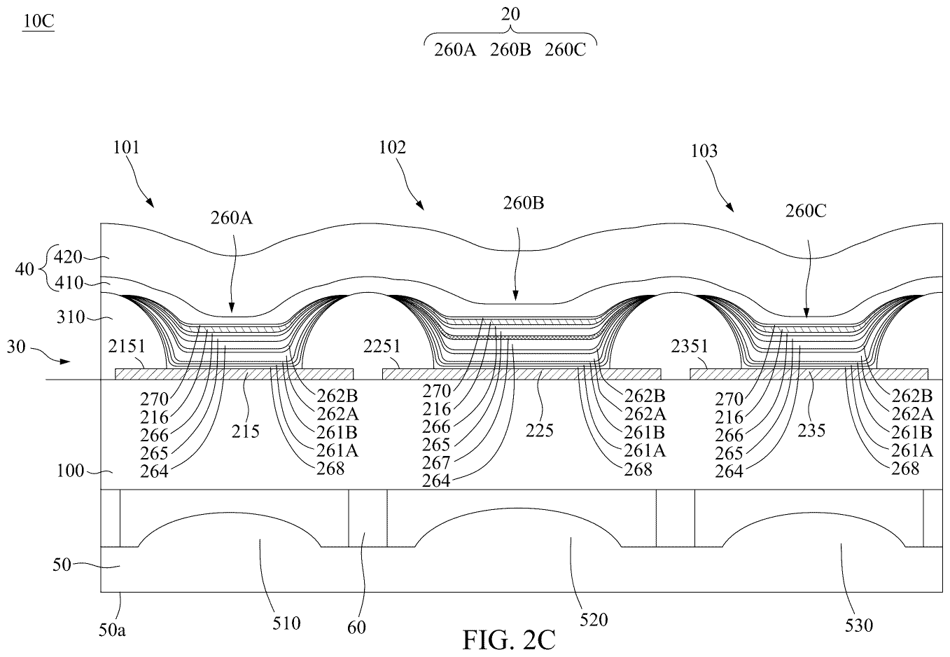

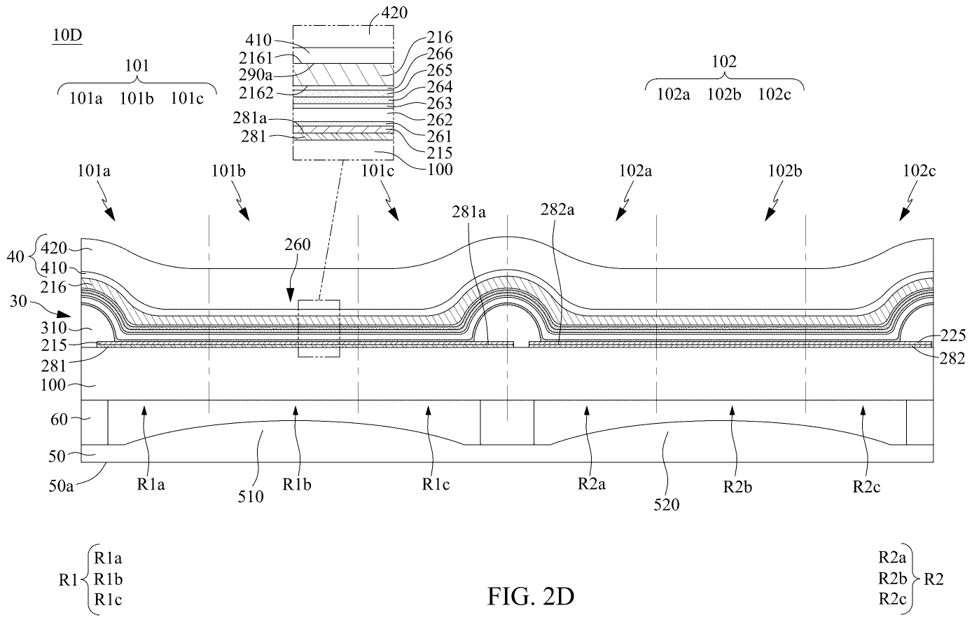

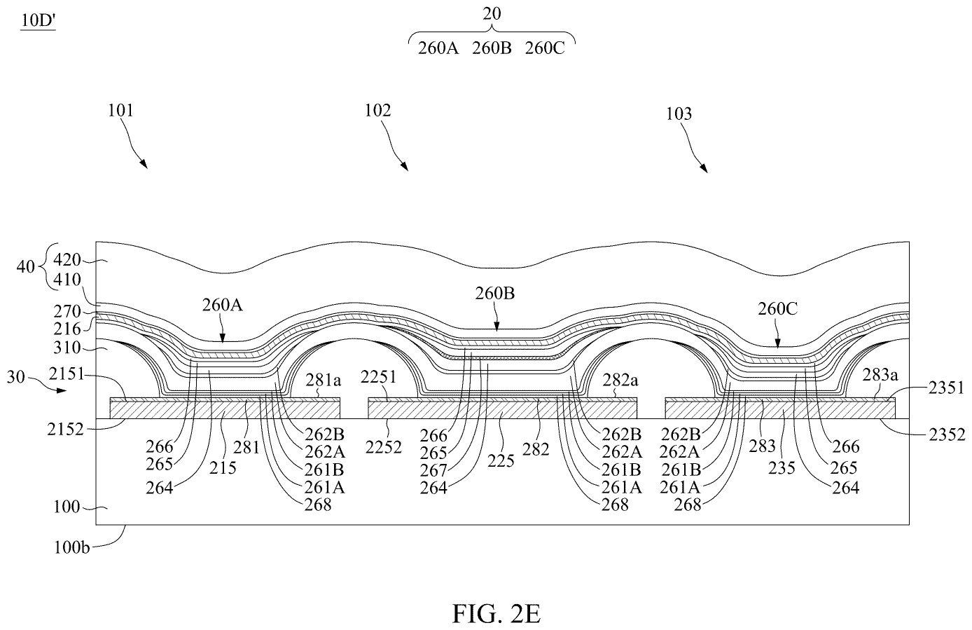

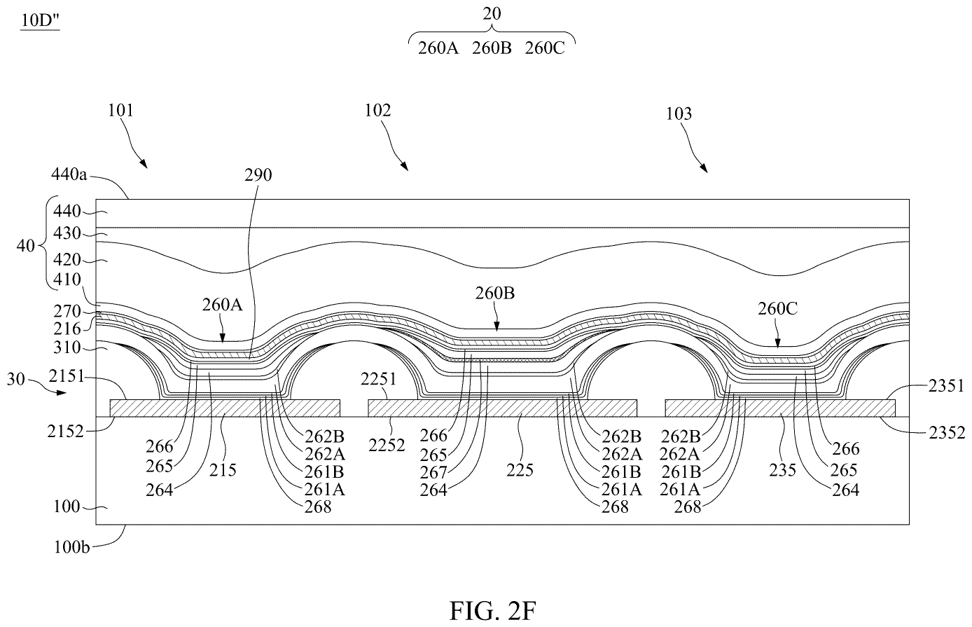

FIG. 2A is a cross sectional view exemplarily showing an organic light emitting element 10A. In some embodiments, FIG. 2A is a cross sectional view exemplarily taken along line 1A-1A′ in FIG. 1. In some embodiments, FIG. 2A is a cross sectional view exemplarily taken along line 1A-1A′ in FIG. 1 and illustrating only a light emitting region. The spacer structure 30 has a plurality of protrusions 310 to define a light emitting pixel pattern. A recess is located between two adjacent protrusions 310 and provides space for accommodating a light emitting pixel. One skilled in the art should understand that the protrusions 310 are shown to be disconnected in the cross sectional view of FIG. 2A, but they are shown to be connectable to each other through other portions of the spacer structure 30 in the top view of FIG. 1.

As shown in FIG. 2A, in some embodiments, the organic light emitting element 10 is, for example, a light emitting device including an organic light emitting diode (OLED) structure. In some embodiments, the organic light emitting element 10 includes a plurality of organic light emitting units (also referred to as light emitting pixels), for example, includes at least an organic light emitting unit 101 (also referred to as a first organic light emitting unit), an organic light emitting unit 102 (also referred to as a second organic light emitting unit), and an organic light emitting unit 103 (also referred to as a third organic light emitting unit). In some embodiments, the organic light emitting units 101, 102, and 103 are located between the protrusions 310 and above a substrate 100. The organic light emitting units 101, 102, and 103 may emit light of the same wavelength or light of different wavelengths.

In some embodiments, the organic light emitting element 10 includes a substrate 100, an electrode 215, an electrode 225, an electrode 235, an electrode 216, the light emitting layer 20, an inorganic barrier layer 268, an inorganic barrier layer 270, a reflective layer 281, a reflective layer 282, a reflective layer 283, the spacer structure 30, and the covering layer 40.

In some embodiments, the substrate 100 may include a transistor array arranged corresponding to the light emitting pixels in the light emitting layer 20. The substrate 100 may include several capacitors. In some embodiments, more than one transistor is arranged together with a capacitor and a light emitting pixel to form a circuit. In some embodiments, the substrate 100 may include glass.

In some embodiments, the electrode 215, the electrode 225, and the electrode 235 are disposed on the substrate 100. In some embodiments, the electrodes 215, 225, and 235 are anodes. In some embodiments, the electrodes 215, 225, and 235 include a metal material, such as Ag, Al, Mg, Au, AlCu alloy, AgMo alloy, or the like. In some embodiments, the electrodes 215, 225, and 235 include indium tin oxide (ITO), indium zinc oxide (ITO), or any other suitable material.

In some embodiments, the light emitting layer 20 includes an organic light emitting layer 260A (also referred to as a first organic light emitting layer), an organic light emitting layer 260B (also referred to as a second organic light emitting layer), and an organic light emitting layer 260C (also referred to as a third organic light emitting layer). In some embodiments, the organic light emitting layer 260A is disposed on the electrode 215, the organic light emitting layer 260B is disposed on the electrode 225, and the organic light emitting layer 260C is disposed on the electrode 235. In some embodiments, a thickness of the organic light emitting layer 260A, a thickness of the organic light emitting layer 260B, and a thickness of the organic light emitting layer 260C are all different. In some embodiments, the thickness of the organic light emitting layer 260B is greater than the thickness of the organic light emitting layer 260A, and the thickness of the organic light emitting layer 260A is greater than the thickness of the organic light emitting layer 260C.

In some embodiments, the organic light emitting layers 260A, 260B, and 260C emit light of the same color or light of different colors. In some embodiments, a wavelength of light emitted from the organic light emitting layer 260B is greater than a wavelength of light emitted from the organic light emitting layer 260A, and the wavelength of light emitted from the organic light emitting layer 260A is greater than a wavelength of light emitted from the organic light emitting layer 260C. In some embodiments, the organic light emitting layer 260A emits green light, the organic light emitting layer 260B emits red light, and the organic light emitting layer 260C emits blue light.

In some embodiments, organic material layers of the organic light emitting layers 260A, 260B, and 260C include an organic material, which may be disposed in any of the organic material layers of the organic light emitting layers 260A, 260B, and 260C based on different implementations. In some embodiments, the organic material has an absorptivity equal to or greater than 50% for a specific wavelength. In some embodiments, the organic material has an absorptivity equal to or greater than 60% for a specific wavelength. In some embodiments, the organic material has an absorptivity equal to or greater than 70% for a specific wavelength. In some embodiments, the organic material has an absorptivity equal to or greater than 80% for a specific wavelength. In some embodiments, the organic material has an absorptivity equal to or greater than 90% for a specific wavelength. In some embodiments, the organic material has an absorptivity equal to or greater than 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2, in some embodiments, the organic light emitting unit 101 includes the electrode 215, the organic light emitting layer 260A, and the electrode 216. In some embodiments, the organic light emitting layer 260A includes a plurality of organic material layers, such as a hole injection layer (HIL) 261A, a hole injection layer (HIL) 261B, a hole transport layer (HTL) 262A, a hole transport layer (HTL) 262B, an organic emissive layer (EM) 264, an electron transport layer (ETL) 265, and an electron injection layer (EIL) 266. In some embodiments, the electrode 216 is disposed above the organic light emitting layer 260A.

As shown in FIG. 2, in some embodiments, the organic light emitting unit 102 includes the electrode 225, the organic light emitting layer 260A, and the electrode 216. In some embodiments, the organic light emitting layer 260B includes a plurality of organic material layers, such as a hole injection layer (HIL) 261A, a hole injection layer (HIL) 261B, a hole transport layer (HTL) 262A, a hole transport layer (HTL) 262B, an organic emissive layer (EM) 264, an electron transport layer (ETL) 265, and an electron injection layer (EIL) 266. In some embodiments, the electrode 216 is disposed above the organic light emitting layer 260B.

As shown in FIG. 2, in some embodiments, the organic light emitting unit 103 includes the electrode 235, the organic light emitting layer 260C, and the electrode 216. In some embodiments, the organic light emitting layer 260C includes a plurality of organic material layers, such as a hole injection layer (HIL) 261A, a hole injection layer (HIL) 261B, a hole transport layer (HTL) 262A, a hole transport layer (HTL) 262B, an organic emissive layer (EM) 264, an electron transport layer (ETL) 265, and an electron injection layer (EIL) 266. In some embodiments, the electrode 216 is disposed above the organic light emitting layer 260C.

In some embodiments, the electrode 216 contacts the organic light emitting layers 260A, 260B, and 260C. The electrode 216 may be a continuous film as shown in FIG. 2 and is disposed above the organic light emitting layers 260A, 260B, and 260C and the protrusions 310. In some embodiments, the electrodes 216 may be further disposed on the spacer structure 30.

In some embodiments, the electrode 216 is a common electrode for all light emitting pixels in the light emitting layer 20. In some embodiments, the electrode 216 includes a metal material, such as Ag, Al, Mg, Au, AlCu alloy, AgMo alloy, or the like. In some embodiments, the electrode 216 includes ITO, IZO, or any other suitable material. In other words, the electrode 216 is a common electrode for several organic light emitting units. In some embodiments, the electrode 216 is a common electrode for all organic light emitting units in the organic light emitting element 10A.

In some embodiments, the reflective layer 281 is disposed between the substrate 100 and the electrode 215. In some embodiments, a surface 2151 of the electrode 215 faces the electrode 216, and a surface 2152 of the electrode 215 opposite to the surface 2151 faces the substrate 100 and contacts the reflective layer 281. In some embodiments, the reflective layer 281 includes a reflective surface 281a (also referred to as a first reflective surface), the electrode 216 includes a surface 2162 (also referred to as a second reflective surface), the reflective surface 281a faces the organic light emitting layer 260A, and the surface 2162 faces the organic light emitting layer 260A. In some embodiments, the electrode 215 is a transparent electrode, and the reflective surface 281a is used to further reflect the light emitted from the organic light emitting layer 260A. In some embodiments, the reflective surface 281a faces away from a light emitting surface (e.g., a lower surface 100b) of the organic light emitting element 10A, and the reflective surface 281a is closer to the light emitting surface of the organic light emitting element 10A than the surface 2162. In some embodiments, for the light emitted from the organic light emitting layer 260A, the reflective surface 281a has a reflectance equal to or greater than 30%, such as equal to or greater than 40%, equal to or greater than 50%, equal to or greater than 60%, or equal to or greater than 70%. In some embodiments, for the light emitted from the organic light emitting layer 260A, the surface 2162 (or the second reflective surface) has a reflectance greater than the reflectance of the reflective surface 281a (or the first reflective surface), such as equal to or greater than 80%, equal to or greater than 85%, equal to or greater than 90%, or equal to or greater than 95%.

In some embodiments, the reflective layer 282 is disposed between the substrate 100 and the electrode 225. In some embodiments, a surface 2251 of the electrode 225 faces the electrode 216, and a surface 2252 of the electrode 225 opposite to the surface 2251 faces the substrate 100 and contacts the reflective layer 282. In some embodiments, the reflective layer 282 includes a reflective surface 282a (also referred to as a third reflective surface), and the reflective surface 282a faces the organic light emitting layer 260B. In some embodiments, the electrode 225 is a transparent electrode, and the reflective surface 282a is used to further reflect the light emitted from the organic light emitting layer 260B. In some embodiments, the reflective surface 282a faces away from the light emitting surface of the organic light emitting element 10A, and the reflective surface 282a is closer to the light emitting surface of the organic light emitting element 10A than the surface 2162. In some embodiments, for the light emitted from the organic light emitting layer 260A, the reflective surface 282a has a reflectance equal to or greater than 30%, such as equal to or greater than 40%, equal to or greater than 50%, equal to or greater than 60%, or equal to or greater than 70%. In some embodiments, for the light emitted from the organic light emitting layer 260B, the surface 2162 (or the second reflective surface) has a reflectance greater than the reflectance of the reflective surface 282a (or the first reflective surface), such as equal to or greater than 80%, equal to or greater than 85%, equal to or greater than 90%, or equal to or greater than 95%.

In some embodiments, the reflective layer 283 is disposed between the substrate 100 and the electrode 235. In some embodiments, a surface 2351 of the electrode 235 faces the electrode 216, and a surface 2352 of the electrode 235 opposite to the surface 2351 faces the substrate 100 and contacts the reflective layer 283. In some embodiments, the reflective layer 283 includes a reflective surface 283a (also referred to as a fourth reflective surface), and the reflective surface 283a faces the organic light emitting layer 260C. In some embodiments, the electrode 235 is a transparent electrode, and the reflective surface 283a is used to further reflect the light emitted from the organic light emitting layer 260C. In some embodiments, the reflective surface 283a faces away from the light emitting surface of the organic light emitting element 10A, and the reflective surface 283a is closer to the light emitting surface of the organic light emitting element 10A than the surface 2162. In some embodiments, for the light emitted from the organic light emitting layer 260A, the reflective surface 283a has a reflectance equal to or greater than 30%, such as equal to or greater than 40%, equal to or greater than 50%, equal to or greater than 60%, or equal to or greater than 70%. In some embodiments, for the light emitted from the organic light emitting layer 260A, the surface 2162 (or the second reflective surface) has a reflectance greater than the reflectance of the reflective surface 283a (or the fourth reflective surface), such as equal to or greater than 80%, equal to or greater than 85%, equal to or greater than 90%, or equal to or greater than 95%.

In some embodiments, when a reflective surface (or a first reflective surface) has a reflectance equal to or greater than 30%, the full width at half maximum (FWHM) of an emission spectrum peak of the organic light emitting layer can be reduced by 10% or more. In some embodiments, when a reflective surface (or a first reflective surface) has a reflectance equal to or greater than 40%, the full width at half maximum (FWHM) of an emission spectrum peak of the organic light emitting layer can be reduced by 15% or more. In some embodiments, when a reflective surface (or a first reflective surface) has a reflectance equal to or greater than 50%, the full width at half maximum (FWHM) of an emission spectrum peak of the organic light emitting layer can be reduced by 20% or more. In some embodiments, when a reflective surface (or a first reflective surface) has a reflectance equal to or greater than 60%, the full width at half maximum (FWHM) of an emission spectrum peak of the organic light emitting layer can be reduced by 25% or more.

In some embodiments, when a reflective surface (or a first reflective surface) has a reflectance equal to or greater than 30%, an emission divergence angle of the organic light emitting layer is approximately ±60 degrees or less. In some embodiments, when a reflective surface (or a first reflective surface) has a reflectance equal to or greater than 40%, an emission divergence angle of the organic light emitting layer is approximately ±50 degrees or less. In some embodiments, when a reflective surface (or a first reflective surface) has a reflectance equal to or greater than 50%, an emission divergence angle of the organic light emitting layer is approximately ±40 degrees or less. In some embodiments, when a reflective surface (or a first reflective surface) has a reflectance equal to or greater than 60%, an emission divergence angle of the organic light emitting layer is approximately ±30 degrees or less.

In some embodiments, each of the reflective layers 281, 282, and 283 includes a reflective metal or a non-conductive reflective material. In some embodiments, each of the reflective layers 281, 282, and 283 includes Ag, a distributed Bragg reflector (DBR), or any other suitable reflective material. In some embodiments, the greater the thickness of a reflective metal, the higher the reflectance of the reflective metal. In some embodiments, the more layers in a DBR, the higher the reflectance of the DBR.

In some embodiments, the spacer structure 30 is disposed on the substrate 100 and partially covers the electrodes 215, 225, and 235. In some embodiments, the spacer structure 30 is disposed between the organic light emitting layers 260A, 260B, and 260C. In some embodiments, the spacer structure 30 may include the protrusions 310. In some embodiments, a pattern of the spacer structure 30 is designed based on a pixel arrangement. In some embodiments, the spacer structure 30 is used as a pixel defined layer (PDL). In some embodiments, the protrusions 310 define pixel regions. In some embodiments, each protrusion 310 fills into a gap between adjacent two of the electrodes 215, 225, and 235. Each of the electrodes 215, 225, and 235 is partially covered by the protrusions 310. In some embodiments, the spacer structure 30 includes an organic insulating material. In some embodiments, the spacer structure 30 includes a light sensitive material. In some embodiments, the spacer structure 30 may further include quantum dots having excellent light absorption efficiency. In some embodiments, the spacer structure 30 may further include a carbon black material, such as carbon black nanoparticles, conductive fibers containing carbon black, or the like. In some embodiments, the spacer structure 30 may further include a black body material having an absorptivity of 90%, 95%, 99%, 99.5%, or 99.9% or more for visible light.

In some embodiments, the spacer structure 30 has an absorptivity equal to or greater than 50% for a specific wavelength. In some embodiments, the spacer structure 30 has an absorptivity equal to or greater than 60% for a specific wavelength. In some embodiments, the spacer structure 30 has an absorptivity equal to or greater than 70% for a specific wavelength. In some embodiments, the spacer structure 30 has an absorptivity equal to or greater than 80% for a specific wavelength. In some embodiments, the spacer structure 30 has an absorptivity equal to or greater than 90% for a specific wavelength. In some embodiments, the spacer structure 30 has an absorptivity equal to or greater than 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the covering layer 40 includes a capping layer 410, an encapsulation layer 420, a filling layer 430, and a cover plate 440. In some embodiments, the capping layer 410 is disposed on the electrode 216, and is substantially conformal to a non-planar upper surface of the electrode 216. The capping layer 410 may include a dielectric material or an inorganic insulating material, such as silicon oxide. In some embodiments, the capping layer 410 may include a hole transport layer material for extracting light lost inside the organic light emitting element to increase the light emitting efficiency. The capping layer 410 may also be referred to as a light extraction layer.

In some embodiments, the encapsulation layer 420 is disposed on the capping layer 410, and is substantially conformal to a non-planar upper surface of the capping layer 410. The encapsulation layer 420 may include an oxide, such as silicon oxide. In some embodiments, the encapsulation layer 420 is substantially conformal to the non-planar upper surface of the capping layer 410, and includes a plurality of recesses corresponding to the organic light emitting layers 260A, 260B, and 260C. The encapsulation layer 420 may include an organic polymer material, such as an epoxy-based material.

In some embodiments, the filling layer 430 is disposed on the encapsulation layer 420, and a lower surface of the filling layer 430 is substantially conformal to a non-planar upper surface of the encapsulation layer 420. The filling layer 430 may also be referred to as a planarization layer. The filling layer 430 may include an organic polymer material, such as an epoxy-based material.

In some embodiments, the cover plate 440 is disposed on a planar upper surface of the filling layer 430. The cover plate 440 may also be referred to as a protection layer. The cover plate 440 may include a transparent hard cover plate, such as a glass plate. The cover plate 440 may be used to prevent components of the organic light emitting element from being exposed to external moisture, which may lead to component failures and inability to emit light.

In some embodiments, the inorganic barrier layer 268 is disposed between the electrodes 215, 225, and 235 and the organic light emitting layers 260A, 260B, and 260C. In some embodiments, a side surface of the inorganic barrier layer 268 contacts a protrusion 310. In some embodiments, the inorganic barrier layer 268 substantially completely covers interfaces between the electrodes 215, 225, and 235 and the organic light emitting layers 260A, 260B, and 260C. In some embodiments, the inorganic barrier layer 268 includes a transition metal oxide. In some embodiments, the inorganic barrier layer 268 includes MoO3. In some embodiments, the inorganic barrier layer 268 has a thickness equal to or less than 100 Å. In some embodiments, a ratio of the thickness of the inorganic barrier layer 268 to a thickness of the electrodes 215, 225, and 235 is less than 0.1, 0.06, or 0.03. In some embodiments, the inorganic barrier layer 268 together with the hole injection layers 261A and 261B may constitute hole injection layers of the organic light emitting layers 260A, 260B, and 260C.

In some embodiments, the inorganic barrier layer 270 contacts the capping layer 410. In some embodiments, the inorganic barrier layer 270 covers the electrode 216. In some embodiments, the capping layer 410 is disposed on the inorganic barrier layer 270, and separated from the electrode 216 by the inorganic barrier layer 270. In some embodiments, the inorganic barrier layer 270 substantially completely covers an interface between the electrode 216 and the capping layer 410. In some embodiments, the inorganic barrier layer 270 includes a transition metal oxide. In some embodiments, the inorganic barrier layer 270 includes MoO3. In some embodiments, the inorganic barrier layer 270 has a thickness equal to or less than 100 A. In some embodiments, a ratio of the thickness of the inorganic barrier layer 270 to a thickness of the electrode 216 is less than 0.15, 0.1, or 0.05. In some embodiments, a ratio of the thickness of the inorganic barrier layer 270 to a thickness of the capping layer 410 is less than 0.5, 0.3, or 0.15.

According to some embodiments of the disclosure, by designing a reflective surface to face an organic light emitting layer, resonant cavity intensity of the organic light emitting element 10A can be enhanced, thereby improving purity of an emission color and reducing an extraction divergence angle.

Furthermore, according to some embodiments of the disclosure, by designing a reflective layer to be disposed on a surface of a transparent electrode, light can pass through the transparent electrode and be reflected by a surface of the reflective layer, thereby reducing optical losses caused by a non-transparent electrode and simultaneously enhancing both the resonant cavity intensity and emission intensity of the organic light emitting element.

In addition, according to some embodiments of the disclosure, by designing a reflective layer to be disposed on an outer surface of a transparent electrode, an optical length of the resonant cavity can be further increased, such that the optical length of the resonant cavity can be increased from a distance between a lower surface of an upper electrode and an upper surface of a lower electrode (e.g., between a lower surface of the electrode 216 and an upper surface of the electrode 215) to a distance between a lower surface of an upper electrode and a lower surface of a lower electrode (e.g., between the lower surface of electrode 216 and a lower surface of electrode 215). Accordingly, an optical length of the resonant cavity can be adjusted by adjusting a thickness of a transparent electrode, thereby improving luminous efficacy of the organic light emitting element.

Furthermore, according to some embodiments of the disclosure, the inorganic barrier layer 268 can be used to block metal atoms in the electrode 215 from diffusing into the organic light emitting layers 260A, 260B, and 260C (e.g., the hole injection layer 261, the hole transport layer 262, an electron blocking layer 263, and the organic emissive layer 264), thereby preventing quenching and avoiding degradation of luminous efficiency, and thus further improving emission brightness and color rendering index (RA) of the organic light emitting element. Furthermore, according to some embodiments of the disclosure, the inorganic barrier layer 268 has a very small thickness compared to the electrodes 215, 225, and 235, and thus a thickness of the organic light emitting element will not be significantly increased, and an emission path will not be adversely increased.

Furthermore, according to some embodiments of the disclosure, the inorganic barrier layer 270 can be used to block metal atoms in the electrode 216 from diffusing into an organic layer (e.g., the capping layer 410), thereby preventing degradation of luminous efficiency, and thus further improving the emission brightness and the color rendering index (RA) of the organic light emitting element. Furthermore, according to some embodiments of the disclosure, the inorganic barrier layer 270 has a very small thickness compared to the capping layer 410, and thus the thickness of the organic light emitting element will not be significantly increased, and the emission path will not be adversely increased.

FIG. 2B is a cross sectional view exemplarily showing an organic light emitting element 10B. In some embodiments, FIG. 2B is a cross sectional view exemplarily showing the organic light emitting element of FIG. 1. In some embodiments, FIG. 2B is a cross sectional view exemplarily taken along line 1A-1A′ in FIG. 1. In some embodiments, FIG. 2B is a cross sectional view exemplarily taken along line 1A-1A′ in FIG. 1 and illustrating only a light emitting region. FIG. 2B has a structure similar to the structure of FIG. 2A, with a difference described as follows.

In some embodiments, the organic light emitting element 10B includes a reflective layer 290, the electrode 216 is a transparent electrode, and the reflective layer 290 is disposed between the capping layer 410 and the electrode 216. In some embodiments, the reflective layer 290 includes a non-conductive material, such as a distributed Bragg reflector (DBR). In some embodiments, the reflective layer 290 includes a plurality of pairs of non-conductive material layers, and a refractive index difference between each pair of non-conductive material layers is equal to or greater than 0.4. In some embodiments, the reflective layer 290 includes a reflective surface 290a. In some embodiments, a surface 2161 of the electrode 216 faces the capping layer 410 and contacts the reflective layer 290. In some embodiments, the surface 2162 of the electrode 216 faces the electrodes 215, 225, and 235. In some embodiments, for the light emitted from the organic light emitting layers 260A, 260B, and 260C, the reflective surface 290a has a reflectance equal to or greater than 30%, such as equal to or greater than 40%, equal to or greater than 50%, equal to or greater than 60%, or equal to or greater than 70%. In some embodiments, a light emitting surface of the organic light emitting element 10B is a surface 440a of the cover plate 440.

FIG. 2C is a cross sectional view exemplarily showing an organic light emitting element 10C. In some embodiments, FIG. 2C is a cross sectional view exemplarily showing the organic light emitting element 10 of FIG. 1. In some embodiments, FIG. 2C is a cross sectional view exemplarily taken along line 1A-1A′ in FIG. 1. In some embodiments, FIG. 2C is a cross sectional view exemplarily taken along line 1A-1A′ in FIG. 1 and illustrating only a light emitting region. FIG. 2C has a structure similar to the structure of FIG. 2A, with a difference described as follows.

In some embodiments, the electrode 216 is disposed between the electrodes 215, 225, and 235 and a light emitting surface of the organic light emitting element 10C. In some embodiments, the electrodes 215, 225, and 235 are metal electrodes, and the surfaces 2151, 2251, and 2351 of the electrodes 215, 225, and 235 facing the electrode 216 include reflective surfaces. In some embodiments, a thickness of the electrodes 215, 225, and 235 is adjusted such that the surfaces 2151, 2251 and 2351 include the reflective surfaces and, for the light emitted from the organic light emitting layers 260A, 260B, and 260C, they have a reflectance equal to or greater than 30%, such as equal to or greater than 40%, equal to or greater than 50%, equal to or greater than 60%, or equal to or greater than 70%.

In some embodiments, the organic light emitting element 10C further includes a lens structure 50 and a black material 60. In some embodiments, the lens structure 50 includes a plurality of optical collimating lenses 510, 520, and 530 disposed corresponding to the organic light emitting layers 260A, 260B, and 260C, respectively. The optical collimating lenses 510, 520, and 530 are also referred to as a micro lens array (MLA). In some embodiments, a distance between the optical collimating lenses 510, 520, and 530 and the organic light emitting units 101, 102, and 103 is adjusted to be close to or equal to the focal lengths of the optical collimating lenses 510, 520, and 530 such that the organic light emitting units 101, 102, and 103 are positioned at focal points of the optical collimating lenses 510, 520, and 530, and thus collimated light beams can be produced. In some embodiments, the black material 60 may be used to prevent the lights emitted from the organic light emitting units 101, 102, and 103 from cross talking with each other. In some embodiments, the light emitting surface of the organic light emitting element 10C is a surface 50a of the lens structure 50.

FIG. 2D is a cross sectional view exemplarily showing an organic light emitting element 10D. In some embodiments, FIG. 2D is a cross sectional view exemplarily showing the organic light emitting element 10 of FIG. 1. In some embodiments, FIG. 2D is a cross sectional view exemplarily taken along line 1B-1B′ in FIG. 1. In some embodiments, FIG. 2D is a cross sectional view exemplarily taken along line 1B-1B′ in FIG. 1 and illustrating only a light emitting region. FIG. 2D has a structure similar to the structure of FIG. 2A, with a difference described as follows.

In some embodiments, the substrate 100 has at least pixel regions R1 and R2, the pixel region R1 corresponds to the organic light emitting unit 101, and the pixel region R2 corresponds to the organic light emitting unit 102. In some embodiments, the pixel region R1 includes a sub-pixel region R1a, a sub-pixel region R1b, and a sub-pixel region R1c corresponding to an organic light emitting sub-unit 101a, an organic light emitting sub-unit 101b, and an organic light emitting sub-unit 101c, respectively. In some embodiments, the pixel region R2 includes a sub-pixel region R2a, a sub-pixel region R2b, and a sub-pixel region R2c corresponding to an organic light emitting sub-unit 102a, an organic light emitting sub-unit 102b, and an organic light emitting sub-unit 102c, respectively.

In some embodiments, the light emitting layer 20 includes an organic light emitting layer 260. In some embodiments, the organic light emitting layer 260 includes a plurality of organic material layers, such as a hole injection layer 261, a hole transport layer 262, an electron blocking layer (EBL) 263, an organic emissive layer 264, an electron transport layer 265, and an electron injection layer 266.

In some embodiments, the organic light emitting element 10D includes the reflective layers 281 and 282, the electrodes 215 and 225 are transparent electrodes, and the reflective layers 281 and 282 are further disposed between the substrate 100 and the electrodes 215 and 225. In some embodiments, the reflective layers 281 and 282 include a non-conductive material, such as a distributed Bragg reflector (DBR). In some embodiments, the reflective layers 281 and 282 include a plurality of pairs of non-conductive material layers, and a refractive index difference between each pair of non-conductive material layers is equal to or greater than 0.4. In some embodiments, the reflective layers 281 and 282 include the reflective surfaces 281a and 282a. In some embodiments, for the light emitted from the organic light emitting layer 260, the reflective surfaces 281a and 282a have a reflectance equal to or greater than 30%, such as equal to or greater than 40%, equal to or greater than 50%, equal to or greater than 60%, or equal to or greater than 70%. In some embodiments, a light emitting surface of the organic light emitting element 10D is a surface 50a of a lens structure 50.

FIG. 2E is a cross sectional view exemplarily showing an organic light emitting element 10D. In some embodiments, FIG. 2E is a cross sectional view exemplarily showing the organic light emitting element 10 of FIG. 1. In some embodiments, FIG. 2E is a cross sectional view exemplarily taken along line 1B-1B′ in FIG. 1. In some embodiments, FIG. 2E is a cross sectional view exemplarily taken along line 1B-1B′ in FIG. 1 and illustrating only a light emitting region. FIG. 2E has a structure similar to the structure of FIG. 2A, with a difference described as follows.

In some embodiments, the organic light emitting element 10D′ includes reflective layers 281, 282, and 283 further disposed between the organic light emitting layers 260A, 260B, and 260C and the electrodes 215, 225, and 235. In some embodiments, the reflective layers 281, 282, and 283 include reflective surfaces 281a, 282a, and 283a. In some embodiments, for the light emitted from the organic light emitting layers 260A, 260B, and 260C, the reflective surfaces 281a, 282a, and 283a have a reflectance equal to or greater than 30%, such as equal to or greater than 40%, equal to or greater than 50%, equal to or greater than 60%, or equal to or greater than 70%. In some embodiments, a light emitting surface of the organic light emitting element 10D is the surface 100b of the substrate 100.

FIG. 2F is a cross sectional view exemplarily showing an organic light emitting element 10D″. In some embodiments, FIG. 2F is a cross sectional view exemplarily showing the organic light emitting element 10 of FIG. 1. In some embodiments, FIG. 2F is a cross sectional view exemplarily taken along line 1B-1B′ in FIG. 1. In some embodiments, FIG. 2F is a cross sectional view exemplarily taken along line 1B-1B′ in FIG. 1 and illustrating only a light emitting region. FIG. 2F has a structure similar to the structure of FIG. 2A, with a difference described as follows.

In some embodiments, the organic light emitting element 10D″ includes a reflective layer 290 further disposed between the organic light emitting layers 260A, 260B, and 260C and the electrode 216. In some embodiments, the reflective layer 290 includes a reflective surface 290a. In some embodiments, for the light emitted from the organic light emitting layers 260A, 260B, and 260C, the reflective surface 290a has a reflectance equal to or greater than 30%, such as equal to or greater than 40%, equal to or greater than 50%, equal to or greater than 60%, or equal to or greater than 70%. In some embodiments, a light emitting surface of the organic light emitting element 10D″ is a surface 440a of the cover plate 440.

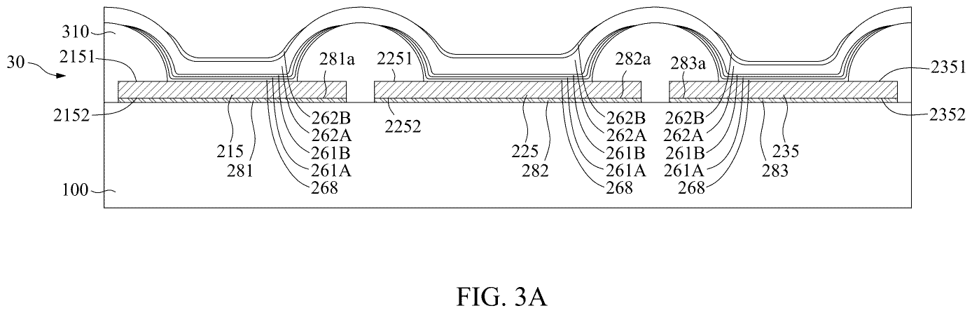

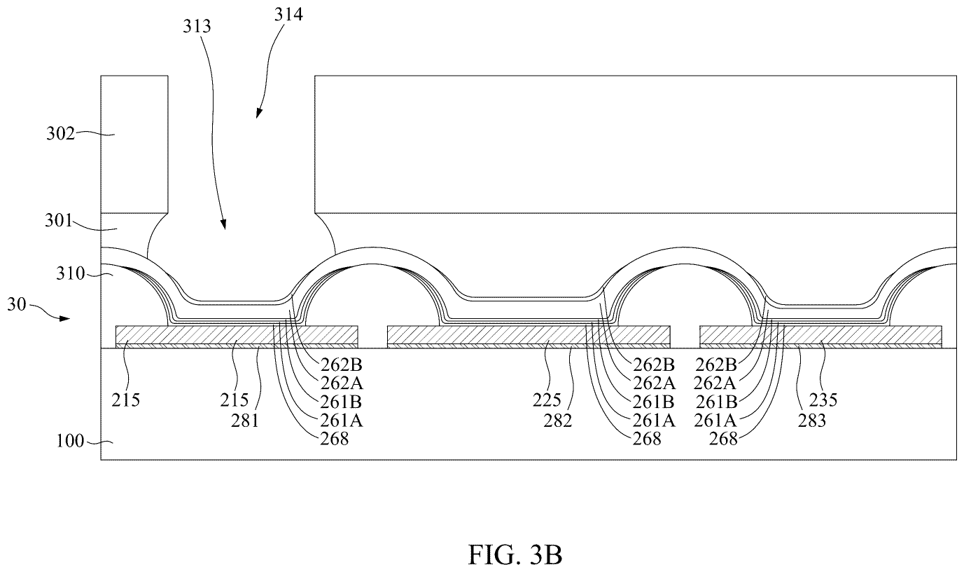

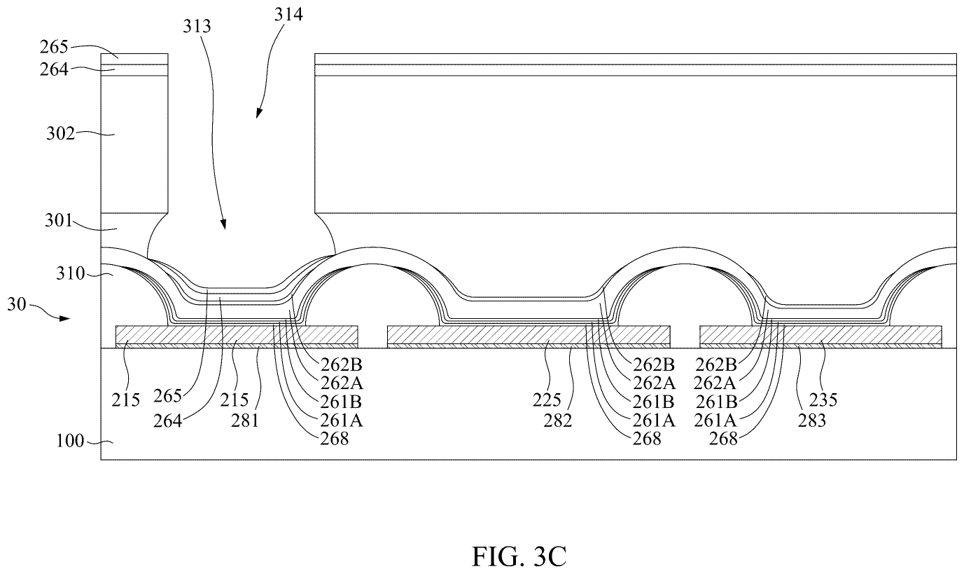

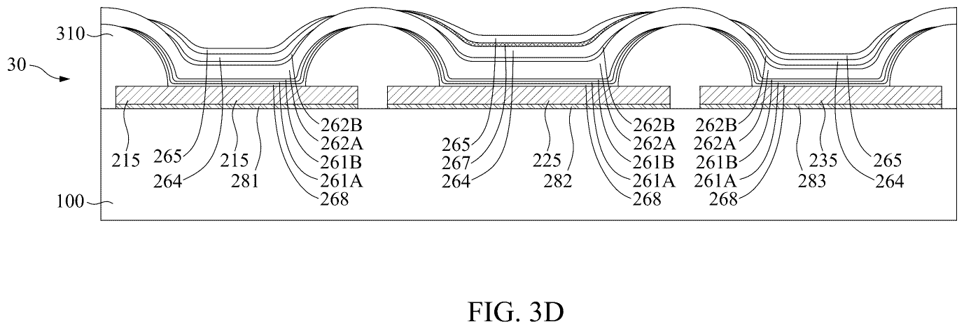

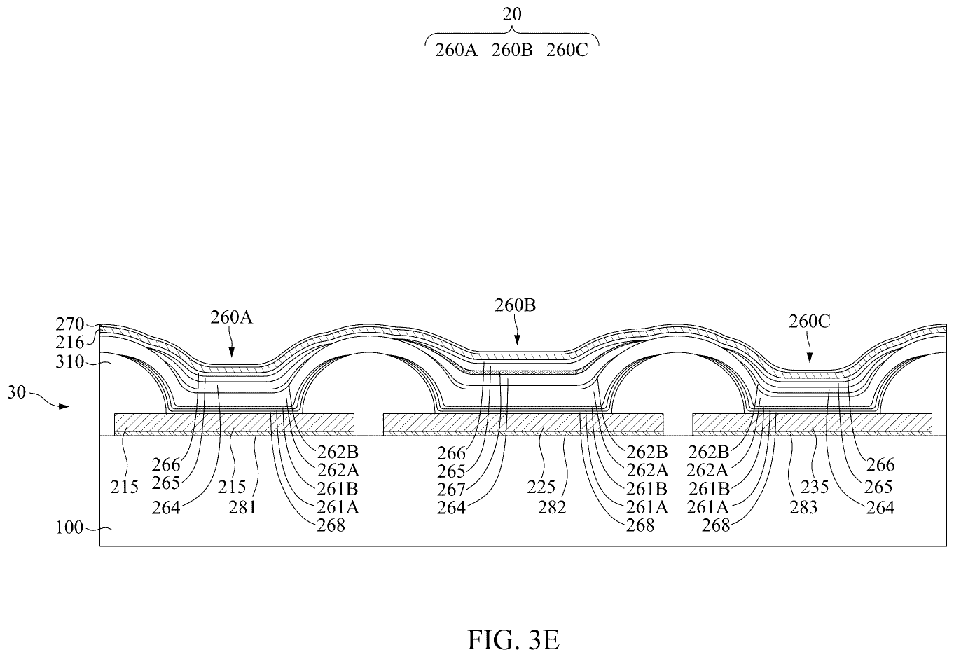

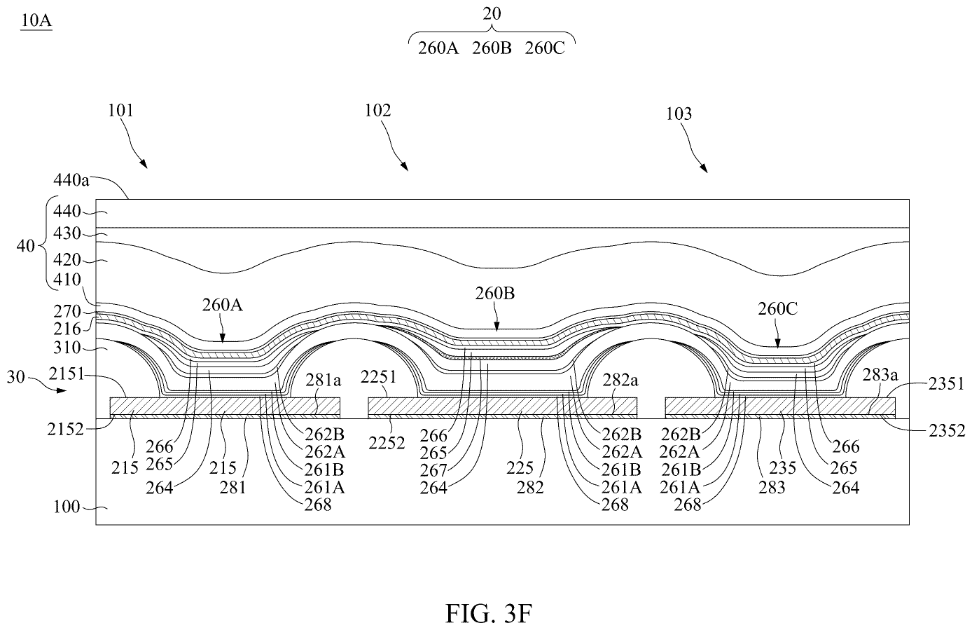

FIGS. 3A-3F show a method of manufacturing the organic light emitting element 10A according to some embodiments.

As shown in FIG. 3A, in some embodiments, a substrate 100 is provided, a plurality of reflective layers 281, 282, and 283 are disposed on the substrate 100, a plurality of electrodes 215, 225, and 235 are disposed on the reflective layers 281, 282, and 283 to form a plurality of protrusions 310 (or a spacer structure 30), and each protrusion 310 fills into a gap between adjacent two of the electrodes 215, 225, and 235. In some embodiments, each protrusion 310 fills into a gap between adjacent two of the reflective layers 281, 282, and 283. In some embodiments, the electrodes 215, 225, and 235 are manufactured using a transparent conductive material. In some embodiments, reflective surfaces (the reflective surfaces 281a, 282a, and 283a of the reflective layers 281, 282, and 283) are formed at lower surfaces (the surfaces 2152, 2252, and 2352) of the electrodes 215, 225, and 235.

Then, in some embodiments, an inorganic barrier layer 268, a hole injection layer (HIL) 261A, a hole injection layer (HIL) 261B, a hole transport layer (HTL) 262A, and a hole transport layer (HTL) 262B are disposed on surfaces of the protrusions 310 and the electrodes 215, 225, and 235. In some embodiments, the inorganic barrier layer 268, the hole injection layer (HIL) 261A, the hole injection layer (HIL) 261B, the hole transport layer (HTL) 262A, and the hole transport layer (HTL) 262B are formed by evaporation. In some embodiments, the inorganic barrier layer 268, the hole injection layer 261A, the hole injection layer 261B, the hole transport layer 262A, and the hole transport layer 262B may be blanket deposited over the electrodes 215, 225, and 235, and because the inorganic barrier layer 268, the hole injection layer 261A, the hole injection layer 261B, and the hole transport layer 262B are relatively thin, these layers over each of the electrodes 215, 225, and 235 are disconnected from each other by the protrusions 310. Because the hole transport layer 262A is relatively thick, the hole transport layer 262A is formed continuously extending over the electrodes 215, 225, and 235 and the protrusions 310.

As shown in FIG. 3B, in some embodiments, a buffer layer 301 is disposed on the protrusions 310, and the buffer layer 301 also covers the inorganic barrier layer 268, the hole injection layer 261A, the hole injection layer 261B, the hole transport layer 262A, the hole transport layer 262B, and the electrodes 215, 225, and 235. The buffer layer 301 is used to block moisture from penetrating into the protrusions 310 as well as the inorganic barrier layer 268, the hole injection layer 261A, the hole injection layer 261B, the hole transport layer 262A, and the hole transport layer 262B. Then, in some embodiments, a light sensitive layer 302 is disposed on the buffer layer 301. In some embodiments, the buffer layer 301 and the light sensitive layer 302 are formed by coating.

Then, in some embodiments, the light sensitive layer 302 is patterned by a lithography process, such that a portion of the buffer layer 301 is exposed through a recess 314. Then, in some embodiments, a portion of the buffer layer 301 is removed to form a recess 313, thereby exposing the hole transport layer 262B. In some embodiments, the buffer layer 301 is removed by a wet etching process.

As shown in FIG. 3C, in some embodiments, an organic emissive layer (EM) 264 is disposed on the hole transport layer 262B, and then an electron transport layer (ETL) 265 is disposed on the organic emissive layer (EM) 264. In some embodiments, the organic emissive layer (EM) 264 and the electron transport layer (ETL) 265 are formed by evaporation.

As shown in FIG. 3D, in some embodiments, the buffer layer 301, the light sensitive layer 302, and portions of the organic emissive layer 264 and the electron transport layer 265 that are above the light sensitive layer 302 are removed. In some embodiments, the buffer layer 301, the light sensitive layer 302, the portion of the organic emissive layer 264, and the portion of the electron transport layer 265 are removed by a wet etching process. In some embodiments, the steps illustrated in FIGS. 3B-3C are repeated to form the organic emissive layer 264, a hole blocking layer (HBL) 267, and the electron transport layer 265 on the electrode 225, and to form the organic emissive layer 264 and the electron transport layer 265 on the electrode 235.

As shown in FIG. 3E, in some embodiments, an electron injection layer (EIL) 266 is disposed on the protrusions 310 and the electron transport layer 265. Thus, organic light emitting layers 260A, 260B, and 260C (or a light emitting layer 20) are formed. In some embodiments, for the light emitted from the organic light emitting layers 260A, 260B, and 260C, the reflective surfaces 281a, 282a, and 283a have a reflectance greater than 30%. Then, in some embodiments, an electrode 216 is disposed on the organic light emitting layers 260A, 260B, and 260C and the spacer structure 30, and an inorganic barrier layer 270 is disposed on the electrode 216. Thus, organic light emitting units 101, 102, and 103 are formed.

As shown in FIG. 3F, in some embodiments, a capping layer 410 is disposed on the inorganic barrier layer 270. In some embodiments, the capping layer 410 is formed by evaporation. Then, in some embodiments, an encapsulation layer 420 is disposed on the capping layer 410. In some embodiments, the encapsulation layer 420 is formed by plasma enhanced chemical vapor deposition (PECVD). Then, in some embodiments, a filling layer 430 is disposed on the encapsulation layer 420, and a cover plate 440 is disposed on the filling layer 430. Thus, a covering layer 40 is formed, wherein the covering layer 40 includes the capping layer 410, the encapsulation layer 420, the filling layer 430, and the cover plate 440. Thus, as shown in FIG. 3F, an organic light emitting element 10A as shown in FIG. 2A is formed.

In some embodiments, referring to FIG. 2C, the reflective layers 281, 282, and 283 are omitted, and the electrodes 215, 225, and 235 are manufactured using a metal material such that the surfaces 2151, 2251, and 2351 of the electrodes 215, 225, and 235 include reflective surfaces.

In some embodiments, referring to FIG. 2E, reflective surfaces (the reflective surfaces 281a, 282a, and 283a of the reflective layers 281, 282, and 283) are formed at upper surfaces (the surfaces 2151, 2251, and 2351) of the electrodes 215, 225, and 235.

FIG. 4 is a top view exemplarily showing an intermediate product of an organic light emitting element 10′. The organic light emitting element 10′ may include a light emitting layer 20 and a covering layer 40 disposed on the light emitting layer 20. For the light emitting layer 20, a spacer structure 30 may be designed to provide a recess array for accommodating a light emitting pixel array. In some embodiments, the spacer structure 30 is used as a pixel defined layer (PDL). In some embodiments, the spacer structure 30 may include protrusions 310. In some embodiments, the protrusions 310 define pixel regions. In some embodiments, the spacer structure 30 may include a light sensitive material. FIG. 4 has a structure similar to the structure of FIG. 1, with a difference described as follows. As shown in FIG. 4, in some embodiments, the organic light emitting element 10′ may further include a plurality of electrodes 215 and a plurality of electrodes 216, such as electrodes 215a and 215b and electrodes 216a and 216b. In some embodiments, the electrodes 215 are anodes, and the electrodes 216 are cathodes. In some embodiments, the electrodes 215 have an extension direction DR2 substantially perpendicular to an extension direction DR1 of the electrodes 216. The organic light emitting element 10′ may further include a blocking structure 710. In some embodiments, an extension direction DR1 of the electrodes 216 is substantially parallel to an extension direction DR1 of the blocking structure 710. In some embodiments, an extension direction DR2 of the electrodes 215 is substantially perpendicular to the extension direction DR1 of the blocking structure 710.

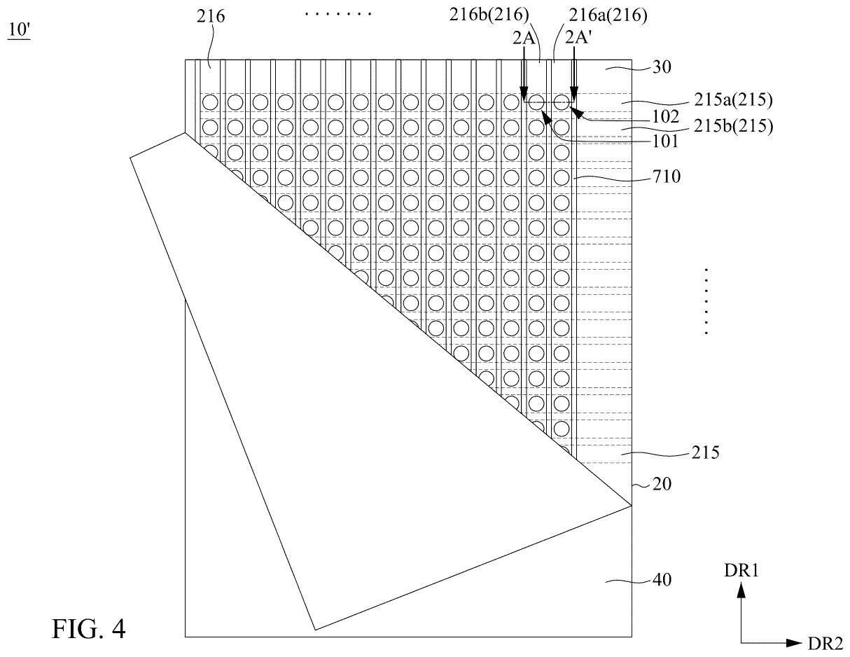

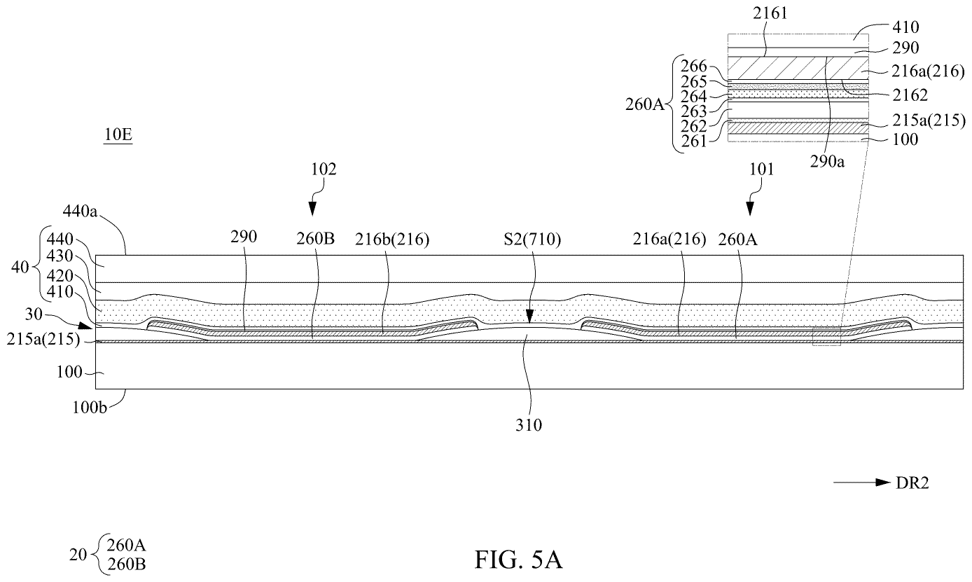

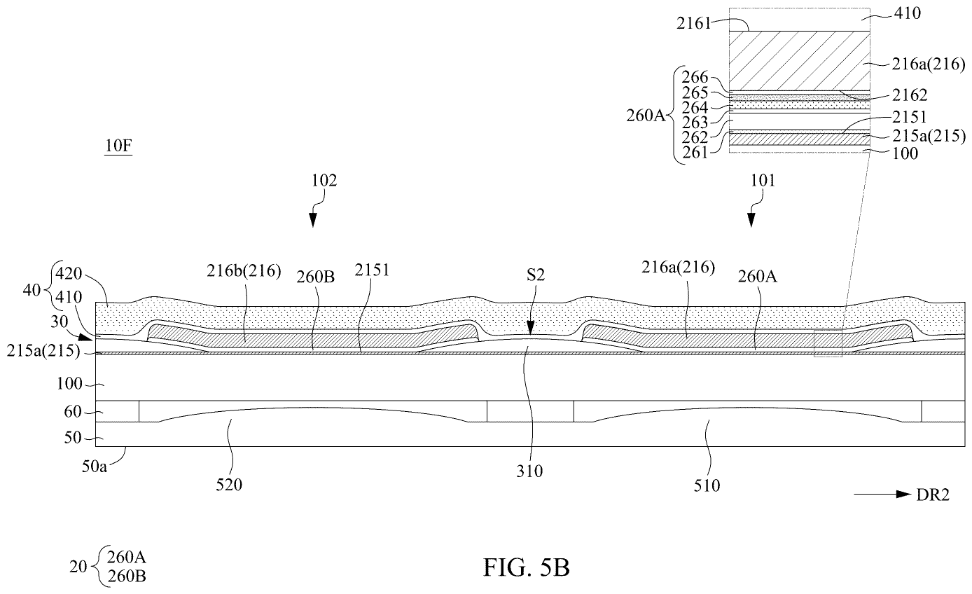

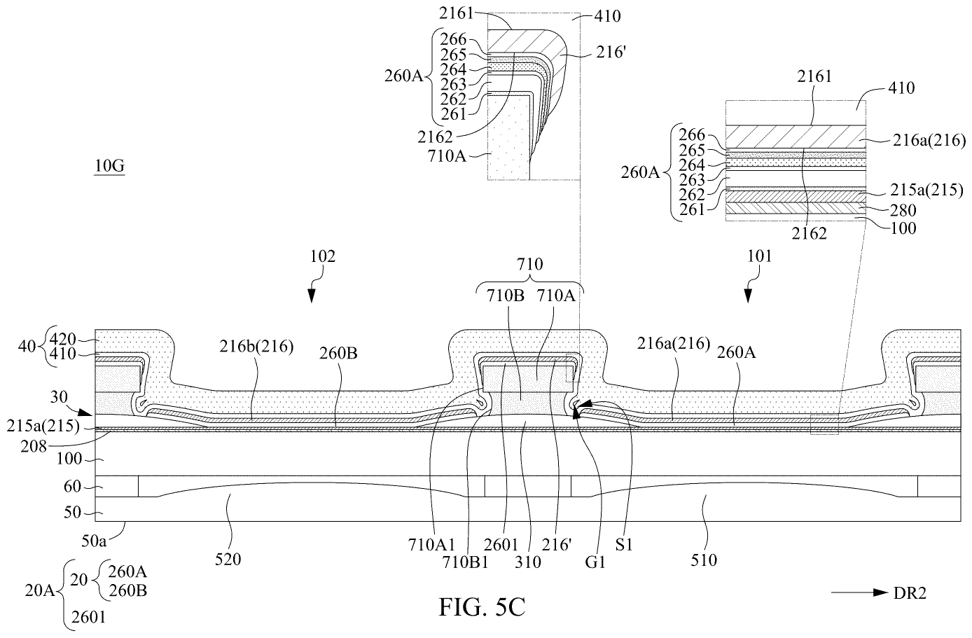

FIG. 5A is a cross sectional view exemplarily showing an organic light emitting element 10E. In some embodiments, FIG. 5A is a cross sectional view exemplarily taken along line 2A-2A′ in FIG. 4. In some embodiments, FIG. 5A is a cross sectional view exemplarily taken along line 2A-2A′ in FIG. 4 and illustrating only a light emitting region. The spacer structure 30 has several protrusions 310 to define a light emitting pixel pattern. A recess is located between two adjacent protrusions 310 and provides space for accommodating a light emitting pixel. One skilled in the art should understand that the protrusions 310 are shown to be disconnected in the cross sectional view of FIG. 5A, but they are shown to be connectable to each other through other portions of the spacer structure 30 in the top view of FIG. 4.

In some embodiments, the electrode 216a and the electrode 216b are separated from each other by a recess S2. In some embodiments, the electrode 216a partially extends onto a protrusion 310 (or the pixel defined layer). In some embodiments, the electrode 216b partially extends onto a protrusion 310 (or the pixel defined layer). In some embodiments, the blocking structure 710 is disposed on a substrate 10. In some embodiments, the blocking structure 710 includes the recess S2. In some embodiments, the electrode 216a and the electrode 216b are separated from each other by the blocking structure 710 (or the recess S2). In some embodiments, the electrode 216a and the electrode 216b are electrically isolated or electrically insulated from each other by the blocking structure 710 (or the recess S2). In some embodiments, the electrodes 216a and 216b and a portion of the upper surface of the spacer structure 30 (or the pixel defined layer) define the recess S2. In some embodiments, the electrodes 216a and 216b are transparent electrodes and are disposed on the substrate 100, and two reflective layers 290 are disposed between the electrodes 216a and 216b and a capping layer 410, respectively. In some embodiments, each of the two reflective layers 290 includes a reflective surface 290a. In some embodiments, for light emitted from organic light emitting layers 260A and 260B, the reflective surfaces 290a have a reflectance equal to or greater than 30%, such as equal to or greater than 40%, equal to or greater than 50%, equal to or greater than 60%, or equal to or greater than 70%.

In some embodiments, the capping layer 410 covers the electrode 216a and the electrode 216b and partially extends into the recess S2. In some embodiments, an encapsulation layer 420 covers the electrode 216a and the electrode 216b and partially extends into the recess S2. In some embodiments, the reflective layers 290 are disposed between the capping layer 410 and the electrodes 216a and 216b. In some embodiments, surfaces 2161 of the electrodes 216a and 216b face the capping layer 410 and contact the reflective layers 290. In some embodiments, a light emitting surface of the organic light emitting element 10E is a surface 440a of a cover plate 440.

FIG. 5B is a cross sectional view exemplarily showing an organic light emitting element 10F. In some embodiments, FIG. 5B is a cross sectional view exemplarily showing the organic light emitting element of FIG. 4. In some embodiments, FIG. 5B is a cross sectional view exemplarily taken along line 2A-2A′ in FIG. 4. In some embodiments, FIG. 5B is a cross sectional view exemplarily taken along line 2A-2A′ in FIG. 4 and illustrating only a light emitting region. FIG. 5B has a structure similar to the structure of FIG. 5A, with a difference described as follows.

In some embodiments, the organic light emitting element 10F further includes a lens structure 50 and a black material 60. In some embodiments, a light emitting surface of the organic light emitting element 10F is a surface 50a of the lens structure 50.

In some embodiments, the electrode 215a is disposed between the electrodes 216a and 216b and the light emitting surface of the organic light emitting element 10F (the surface 50a). In some embodiments, the electrodes 215 are metal electrodes, and a surface 2151 of an electrode 215 facing the electrodes 216a and 216b includes a reflective surface (or a first reflective surface). In some embodiments, the electrodes 216a and 216b are metal electrodes, and surfaces 2162 of the electrodes 216a and 216b facing the electrode 215a includes reflective surfaces (or second reflective surfaces). In some embodiments, a thickness of the electrode 215 is adjusted such that, for the light emitted from the organic light emitting layers 260A and 260B, the surface 2151 has a reflectance equal to or greater than 30%, such as equal to or greater than 40%, equal to or greater than 50%, equal to or greater than 60%, or equal to or greater than 70%, and the surfaces 2162 have a reflectance greater than the reflectance of the surface 2151.

FIG. 5C is a cross sectional view exemplarily showing an organic light emitting element 10G. In some embodiments, FIG. 5C is a cross sectional view exemplarily showing the organic light emitting element 10 of FIG. 4. In some embodiments, FIG. 5C is a cross sectional view exemplarily taken along line 2A-2A′ in FIG. 4. In some embodiments, FIG. 5C is a cross sectional view exemplarily taken along line 2A-2A′ in FIG. 4 and illustrating only a light emitting region. FIG. 5C has a structure similar to the structure of FIG. 5A, with a difference described as follows.

In some embodiments, the blocking structure 710 includes a blocking strip 710A and a blocking strip 710B. In some embodiments, a sidewall 710B1 of the blocking strip 710B is recessed relative to a sidewall 710A1 of the blocking strip 710A. In some embodiments, the sidewall 710B1 of the blocking strip 710B includes a concave curved surface. In some embodiments, the blocking strip 710A and the blocking strip 710B may include different inorganic oxide, for example, the blocking strip 710A may include silicon oxide, and the blocking strip 710B may include silicon nitride or silicon oxynitride. In some embodiments, the encapsulation layer 420 further has a gap G1. In some embodiments, the gap G1 is located in a space S1.

In some embodiments, an electrode material layer 216′ is disposed on an upper surface and sidewalls of the blocking structure 710, and the electrode material layer 216′ is separated from the electrode 216a and the electrode 216b. In some embodiments, an organic light emitting layer structure 20A includes the light emitting layer 20 and an organic material layer 2601. In some embodiments, the organic material layer 2601 includes an organic material similar to that of the organic light emitting layers 260A and 260B.

In some embodiments, the reflective layer 280 is disposed between the substrate 100 and the electrode 215.

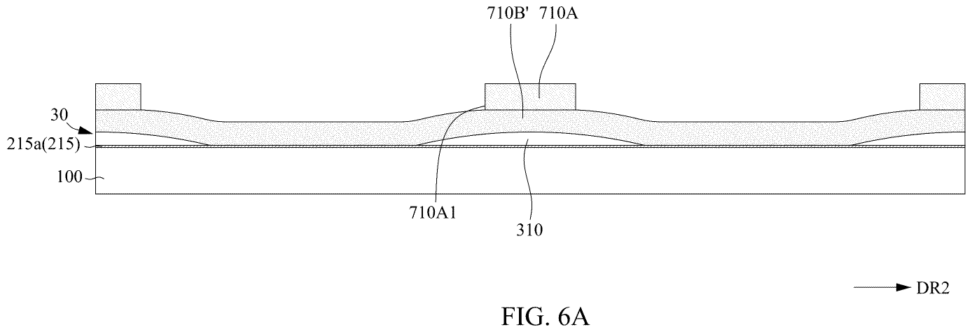

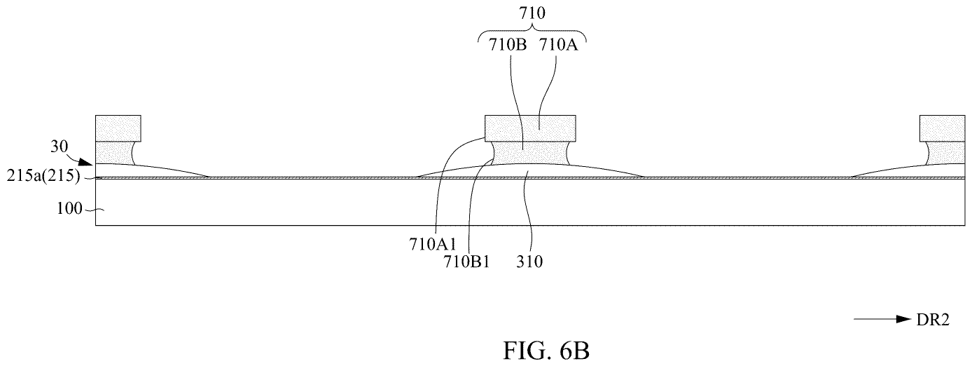

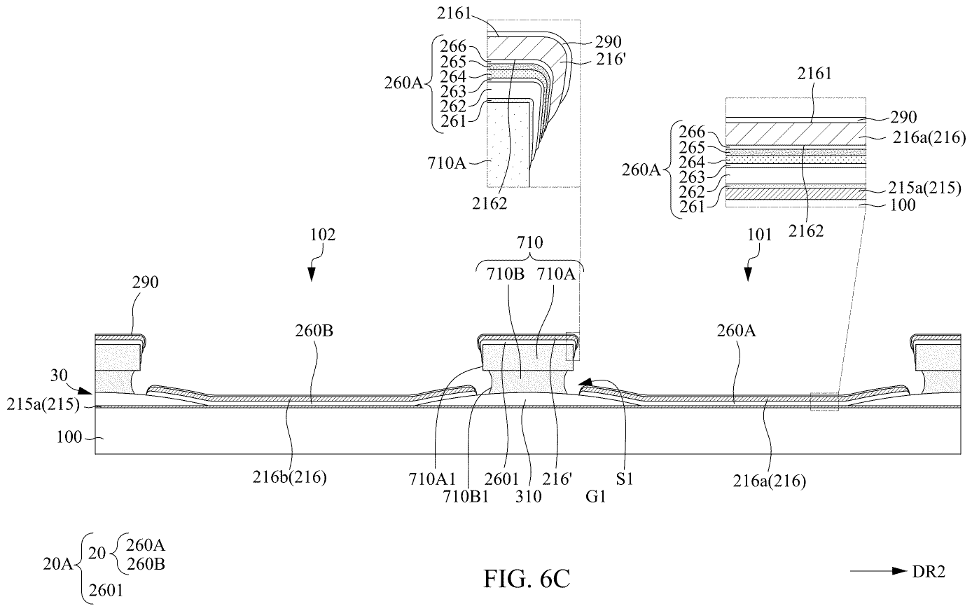

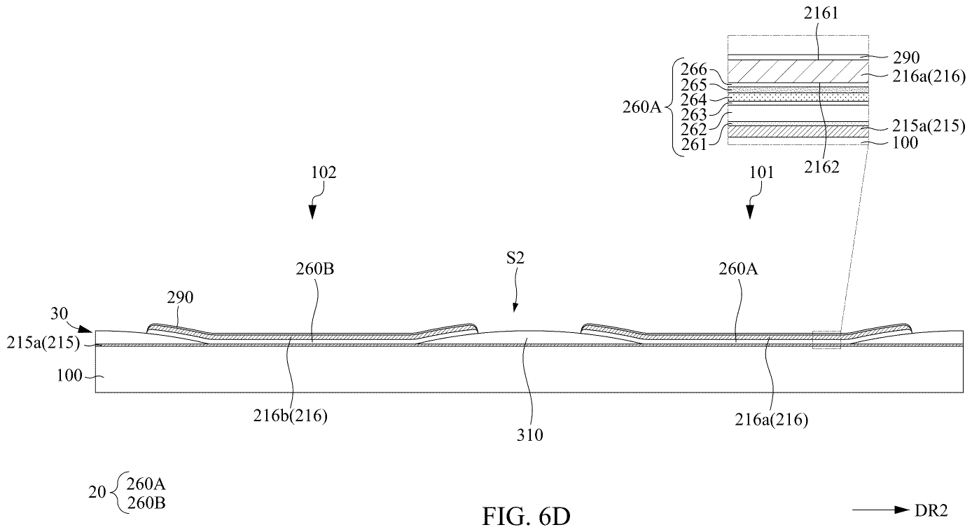

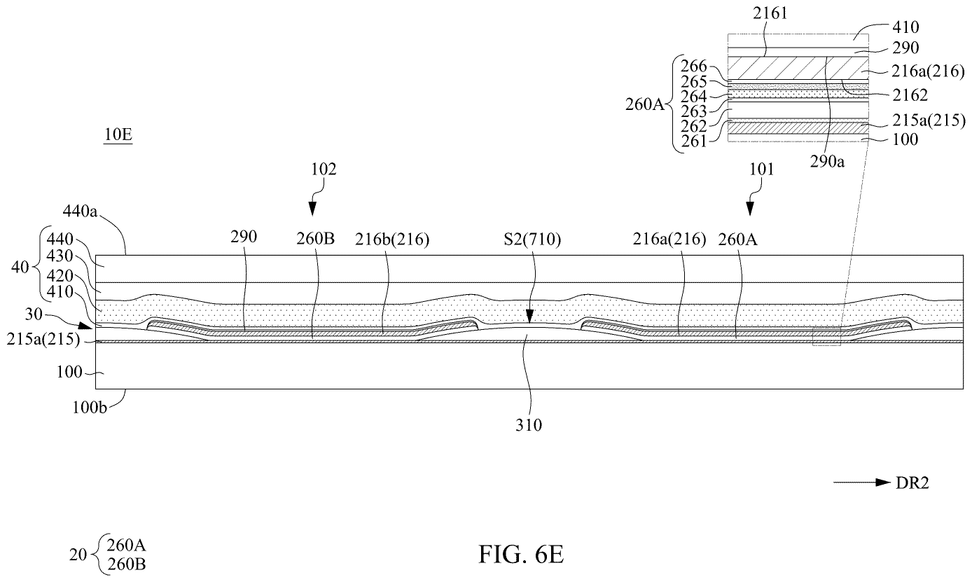

FIGS. 6A-6E show a method of manufacturing the organic light emitting element 10E according to some embodiments.

As shown in FIG. 6A, in some embodiments, a substrate 100 is provided, an electrode 215a is disposed on the substrate100, and a plurality of protrusions 310 (or a spacer structure 30) are formed on the electrode 215a. In some embodiments, a plurality of electrodes 215 are disposed on the substrate 100 (referring to FIG. 4), and the spacer structure 30 is formed on the plurality of electrodes 215. The plurality of electrodes 215 may be manufactured by photolithography and etching processes. Then, in some embodiments, a blocking material layer 710B′ is formed on the electrodes 215 and the protrusions 310 (or the pixel defined layer), and a blocking strip 710A is formed on the blocking material layer 710B′by photolithography and etching processes. In some embodiments, the blocking strip 710A and the blocking material layer 710B′may include different light sensitive materials, for example, the blocking strip 710A and the blocking material layer 710B′may include different photoresist materials.

As shown in FIG. 6B, in some embodiments, the blocking material layer 710B′ is etched based on a pattern of the blocking strip 710A to form a blocking strip 710B, such that a sidewall 710B1 of the blocking strip 710B is recessed relative to a sidewall 710A1 of the blocking strip 710A. In some embodiments, the blocking material layer 710B′ is etched by a wet etching process, such that the sidewall 710B1 of the blocking strip 710B has an undercut structure. In some embodiments, the blocking material layer 710B′ is etched by a wet etching process, such that the sidewall 710B1 of the blocking strip 710B has a concave curved surface. Thus, a blocking structure 710 is formed.

As shown in FIG. 6C, in some embodiments, an organic light emitting layer structure 20A, reflective layers 290, and an electrode material layer 216′are formed on the spacer structure 30, the electrode 215a, and the blocking structure 710.

In some embodiments, the electrode material layer is formed above the blocking structure 710 and the substrate 100, such that the electrode material layer is cut off by the blocking structure 710 to form an electrode 216a and an electrode 216b that are separated from each other. In some embodiments, a whole electrode material layer is formed on the spacer structure 30, the electrode 215a, and the blocking structure 710 by evaporation, such that the whole electrode material layer is cut off by the blocking structure 710 to form electrode 216a and electrode 216b, which are separated from each other, and an electrode material layer 216′ remaining on the blocking structure 710. In some embodiments, electrodes 216a and 216b are manufactured using a transparent conductive material.

In some embodiments, an organic light emitting material layer is formed above the blocking structure 710 and the substrate 100, such that the organic light emitting material layer is cut off by the blocking structure 710 to form an organic light emitting layer 260A and an organic light emitting layer 260B that are separated from each other. In some embodiments, a whole organic light emitting layer is formed on the spacer structure 30, the electrode 215a, and the blocking structure 710 by evaporation, such that the whole electrode material layer is cut off by the blocking structure 710 to form the organic light emitting layer 260A and the organic light emitting layer 260B, which are separated from each other, and an organic material layer 2601 remaining on the blocking structure 710. Thus, organic light emitting units 101 and 102 are formed.

In some embodiments, a hole injection layer 261 is disposed on surfaces of the spacer structure 30, the electrode 215a, and the blocking structure 710, a hole transport layer 262 is disposed on the hole injection layer 261, an electron blocking layer 263 is disposed on the hole transport layer 262, an organic emissive layer 264 is disposed on the electron blocking layer 263, and then an electron transport layer 265 is disposed on the organic emissive layer 264, and an electron injection layer 266 is disposed on the electron transport layer 265. In some embodiments, the hole injection layer 261, the hole transport layer 262, the electron blocking layer 263, the organic emissive layer 264, the electron transport layer 265, and the electron injection layer 266 are formed by evaporation.

In some embodiments, reflective layers 290 are disposed on the electrode 216a, the electrode 216b, and the electrode material layer 216′ remaining on the blocking structure 710.

As shown in FIG. 6D, in some embodiments, the blocking structure 710 is removed to form a recess S2 defined by the electrode 216a, the electrode 216b, and a portion of the upper surface of the protrusions 310 (or the pixel defined layer). In some embodiments, the blocking structure 710 is removed by a lift-off process.

As shown in FIG. 6E, in some embodiments, a capping layer 410 is disposed on the electrode 216a and the electrode 216b. In some embodiments, the capping layer 410 is formed by evaporation. In some embodiments, a capping layer 410 is formed above the electrode 216a and the electrode 216b and partially extending into the recess S2. Then, in some embodiments, an encapsulation layer 420 is disposed on the capping layer 410. In some embodiments, the capping layer 410 is formed by evaporation. Then, in some embodiments, a filling layer 430 is disposed on the encapsulation layer 420, and a cover plate 440 is disposed on the filling layer 430. Thus, a covering layer 40 is formed, wherein the covering layer 40 includes the capping layer 410, the encapsulation layer 420, the filling layer 430, and the cover plate 440. Thus, an organic light emitting element 10E as shown in FIG. 5A is formed.

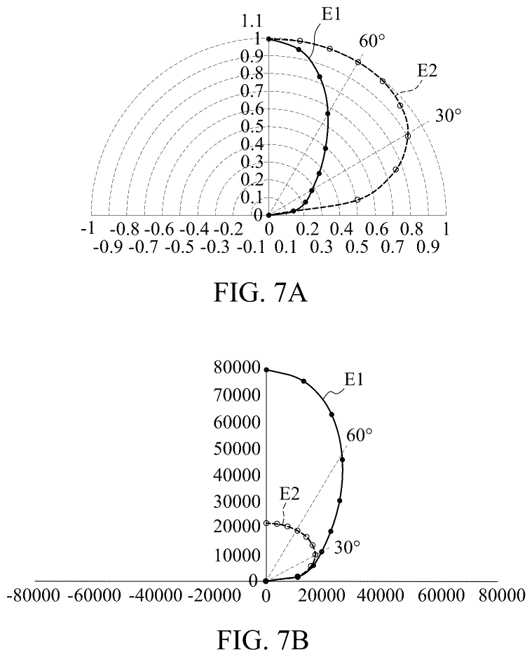

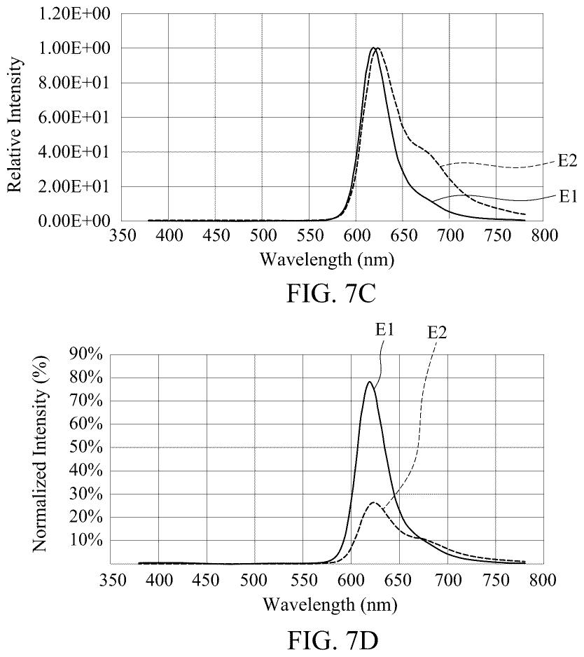

FIG. 7A shows simulation results of spatial luminance distribution of an organic light emitting element according to some embodiments, and FIG. 7B shows simulation results of spatial luminance distribution of an organic light emitting element according to some comparative embodiments.

Curve E1 represents the simulated luminance spatial distribution of an organic light emitting element 10A as shown in FIG. 2A, and curve E2 represents the simulated luminance spatial distribution of an organic light emitting element without a reflective surface. Curves E1 and E2 indicate emission intensity as a function of viewing angle, obtained from far-field measurements at 10° intervals from 0° (normal direction) to 90° (lateral direction). As shown in FIG. 7A, according to some embodiments, the organic light emitting element with a design having a reflective surface or a reflective layer exhibits a higher resonant cavity intensity, the luminance spatial distribution is more concentrated, and an emission direction is more inclined toward the normal direction. In other words, the extraction divergence angle is smaller, and emitted light is more concentrated along the normal direction, and thus directionality of the light is stronger, and the light is more likely to be projected onto a predetermined projection surface. As shown in FIGS. 7A and 7B, by the design of a reflective surface or a reflective layer, the extraction divergence angle can be reduced by more than half.

FIG. 7C shows simulation results of emission peak spectra of an organic light emitting element according to some embodiments, and FIG. 7D shows simulation results of emission peak spectra of an organic light emitting element according to some comparative embodiments.

Curve E1 represents the simulated results of emission peak spectra of an organic light emitting element 10A as shown in FIG. 2A, and curve E2 represents the simulated results of emission peak spectra of an organic light emitting element without a reflective surface. By the design of a reflective surface or a reflective layer, the intensity of the resonance cavity can be enhanced, thereby narrowing the FWHM of the emission peak, and thus enabling enhancement of color purity of emitted light, and a better monochromaticity can be obtained. For example, the FWHM of the emission peak may be reduced by 10%, 20%, or 25% or more.

The aforementioned content generally outlines the features of some implementations, allowing one skilled in the art to better understand various aspects of the disclosure. One skilled in the art should understand that hid disclosure can be easily used as a foundation to design or modify other processes and structures to achieve the same objectives and/or attain the same advantages as the embodiments described in the present application. One skilled in the art should also understand that such equivalent structures do not depart from the spirit and the scope of the disclosed content, and various changes, substitutions, and modifications can be made without departing from the spirit and the scope of the disclosure.

What is claimed is:

1. An organic light emitting element, comprising:
a substrate;
a first electrode and a second electrode disposed on the substrate;
a first organic light emitting layer disposed between the first electrode and the second electrode;
a first reflective surface and a second reflective surface facing the first organic light emitting layer, wherein for light emitted from the first organic light emitting layer, the first reflective surface has a reflectance equal to or greater than 30%, and the second reflective surface has a reflectance greater than the reflectance of the first reflective surface.

2. The organic light emitting element according to claim 1, wherein the first reflective surface faces away from a light emitting surface of the organic light emitting element, and the first reflective surface is closer to the light emitting surface than the second reflective surface.

3. The organic light emitting element according to claim 1, wherein the first electrode is disposed between the second electrode and a light emitting surface of the organic light emitting element, the first electrode is a metal electrode, and a surface of the first electrode facing the second electrode comprises the first reflective surface.

4. The organic light emitting element according to claim 1, wherein the first electrode is disposed between the second electrode and a light emitting surface of the organic light emitting element, the first electrode is a transparent electrode, and the organic light emitting element further comprises:
a reflective layer disposed between the substrate and the first electrode, wherein the reflective layer comprises the first reflective surface.

5. The organic light emitting element according to claim 4, wherein a first surface of the first electrode faces the second electrode, and a second surface of the first electrode opposite to the first surface faces the substrate and contacts the reflective layer.

6. The organic light emitting element according to claim 4, further comprising:
a third electrode disposed on the substrate, wherein the third electrode is a transparent electrode; and
a second organic light emitting layer disposed between the third electrode and the second electrode, wherein the reflective layer is further disposed between the substrate and the third electrode.

7. The organic light emitting element according to claim 1, wherein the first electrode is disposed between the second electrode and a light emitting surface of the organic light emitting element, the first electrode is a transparent electrode, and the organic light emitting element further comprises:
a reflective layer disposed between the first electrode and the first organic light emitting layer, wherein the reflective layer comprises the first reflective surface.

8. The organic light emitting element according to claim 1, wherein the first electrode is disposed between the second electrode and a light emitting surface of the organic light emitting element, the first electrode is a transparent electrode, and the organic light emitting element further comprises:
a capping layer disposed on the first electrode; and
a first reflective layer disposed between the capping layer and the first electrode, wherein the first reflective layer comprises the first reflective surface.

9. The organic light emitting element according to claim 8, wherein a first surface of the first electrode faces the capping layer and contacts the first reflective layer.

10. The organic light emitting element according to claim 8, further comprising:
a third electrode disposed on the substrate, wherein the third electrode is a transparent electrode;
a second organic light emitting layer disposed between the third electrode and the second electrode; and
a second reflective layer disposed between the capping layer and the second electrode, wherein the second reflective layer comprises a third reflective surface.

11. The organic light emitting element according to claim 10, wherein for light emitted from the second organic light emitting layer, the third reflective surface has a reflectance equal to or greater than 30%.

12. A method of manufacturing an organic light emitting element, comprising:
providing a substrate;
disposing a first electrode and a second electrode on the substrate;
forming a first organic light emitting layer on the substrate, wherein the first organic light emitting layer is disposed between the first electrode and the second electrode; and
forming a first reflective surface at a first surface of the first electrode or at a second surface of the first electrode opposite to the first surface, wherein for light emitted from the first organic light emitting layer, the first reflective surface has a reflectance equal to or greater than 30%.

13. The method according to claim 12, further comprising:
manufacturing the first electrode using a metal material, such that the first surface of the first electrode facing the first organic light emitting layer comprises the first reflective surface.

14. The method according to claim 12, further comprising:
manufacturing the first electrode using a transparent conductive material; and
disposing a reflective layer on the first surface or the second surface of the first electrode, wherein the first electrode is disposed between a light emitting surface of the organic light emitting element and the second electrode.

15. The method according to claim 12, further comprising:
disposing a first reflective layer and a second reflective layer separated from each other on the substrate; and
disposing a third electrode on the second reflective layer, wherein the first electrode is disposed on the first reflective layer, and the first electrode and the third electrode comprise a transparent conductive material.

16. The method according to claim 12, further comprising:
forming a second organic light emitting layer on the substrate;
disposing a third electrode on the second organic light emitting layer, wherein the first electrode is disposed on the first organic light emitting layer;
disposing a first reflective layer on the first electrode; and
disposing a second reflective layer on the third electrode.
